(19) United States
(12) Patent Application Publication
(10) Pub. No.: US 2017/0242606 A1
(43) Pub. Date: Aug. 24, 2017

(54) METHODS AND SYSTEMS FOR TRANSITIONING TO AND FROM DIFFERENT STORAGE DEVICE POWER STATES USING HOST MEMORY BUFFER (HMB)

(71) Applicant: SanDisk Technologies LLC, Plano, TX (US)

(72) Inventors: Julian Vlaiko, Kfar Saba (IL); Judah Gamliel Hahn, Ofra (IL); Yevgeny Zagalsky, Kfar Saba (IL)

(21) Appl. No.: 15/047,713

(22) Filed: Feb. 19, 2016

(51) Int. Cl. G06F 3/06; G11C 7/10; G06F 13/42; G06F 1/32; G11C 11/406

(52) U.S. Cl. CPC G06F 3/0625; G06F 3/0688; G06F 3/0619; G06F 1/3287; G11C 11/40615; G06F 13/4282; G11C 7/1072; G06F 3/065; G06F 3/0634

(57) ABSTRACT

The subject matter described herein includes methods, systems, and computer readable media for transitioning to and from storage device low power states using a host memory buffer (HMB). One storage device includes a non-volatile memory. A device controller controls access to the non-volatile memory. A host memory buffer (HMB)-assisted power state transition module operatively associated with the device controller stores storage device state information in a host memory buffer (HMB) in memory of host device separate from the storage device prior to the storage device entering a lower power state and uses the state information stored in the HMB to transition the storage device from the lower power state to a higher power state.

### TECHNICAL FIELD

The subject matter described herein relates to transitioning to and from different storage device power states. More particularly, the subject matter described herein relates to methods and systems for transitioning to and from different storage device power states using a host memory buffer (HMB).

### BACKGROUND

Storage devices, such as non-volatile storage devices, are typically called upon by host devices to operate in different power modes depending on the needs of the host to which they are attached. For example, in non-volatile memory express (NVMe) devices attached to client host platforms, there are generally five power states that the device can use, which are aligned with different host use cases. These power states are referred to by the storage device industry as PS0 through PS4, where PS0 is the active power state and the other power states have gradually decreasing power requirements.

Power states may be operational or nonoperational. A nonoperational power state is one where no commands are processed by the storage device, and this state is generally expected to consume very little power. An operational state is a state where commands are processed. PS0-PS2 are operational power states, and PS3-PS4 are non-operational power states.

In addition to reduced power consumption in the non-operational power states, the transition time from one power state to another is taken into account in the host power strategy governing the transitions. The PS3 power state is expected to be rapidly transitioned into and out of, with a slight transitional power cost. PS4 is expected to have minimal power consumption (on the order of 2 to 5 milliwatts), but is permitted to take more time for transitions than PS3. These transitional periods of time and average power consumption estimates are part of the power strategy deployed by the host in order to maximize battery life on laptops and other portable host devices.

In the current generation of solid state drives (SSDs), the drives include integrated onboard DRAM, such as DDR2/3/4 or LPDDR2/3. Using onboard DRAM allows for rapid PS3 transitions by keeping the DRAM alive in the low power state and storing device context information in the DRAM prior to shutdown. Resume can then occur rapidly from the DRAM. Similarly, in transitions to and from the PS4 state, DRAM may be maintained in self-refresh mode (full array or partial array as in LPDDR devices) so that device context information can be retrieved from the DRAM during startup. In SSDs that use standard DDR or have low power requirements, device context information can be committed to NAND memory during a PS4 transition, but this causes the transition time to be quite long (on the order of greater than 300 milliseconds entry latency and 100 milliseconds exit latency).

In the next generation of solid state drives, it is desirable to reduce cost by eliminating onboard DRAM. This eliminates the ability to do rapid PS4 transitions, since the only option in an SRAM only device that needs to keep power very low is to swap internal context to NAND when powering off and reading the context from NAND when powering on. Even in solid state drives that include on-board DRAM, if the drive is powered off, the onboard DRAM cannot be used to store bootstrap data because the data stored in DRAM is erased when the device is powered off. As a result, bootstrap data is committed to NAND, which has slow access time on resume.

### BRIEF DESCRIPTION OF THE DRAWINGS

The subject matter described herein will now be explained with reference to the accompanying drawings of which:

FIG. 1 is a block diagram of a storage device and a host device, where the storage device uses an HMB maintained by the host device to facilitate transfer to and from different storage device power states;

FIG. 2 is a flow chart illustrating an exemplary process for transitioning to a PS4 power state and using the HMB to store storage device state information;

FIG. 3 is a flow chart illustrating an exemplary process for transitioning from a PS4 to a PS0 power state where the storage device locates and verifies the HMB prior to transitioning to the PS0 state without assistance from the host;

FIG. 4 is a flow chart illustrating an exemplary transition from a PS4 or PS3 power state to a PS0 power state where the storage device relies on the host to inform the storage device that the HMB is the same HMB stored prior to shutdown or transition to the lower power state;

FIG. 5 is a flow chart illustrating an exemplary process for transitioning from a PS3 or PS4 power state to a PS0 power state where the storage device uses a peripheral component interconnect express (PCIe) register to determine the location of the storage device state information stored prior to shutdown; and

FIG. 6 is a flow chart illustrating an exemplary process for transitioning to a PS4 power state for a storage device that includes onboard DRAM.

### DETAILED DESCRIPTION

The subject matter described herein includes methods, systems, and computer readable media for transitioning to and from storage device low power states using a host memory buffer (HMB). One storage device includes a non-volatile memory. A device controller controls access to the non-volatile memory. An HMB-assisted power state transition module operatively associated with the device controller stores storage device state information in the HMB, which is maintained in memory of a host device separate from the storage device, prior to the storage device entering a lower power state and uses the state information stored in the HMB to transition the storage device from the lower power state to a higher power state.

As used herein, the term “storage device state information” refers to information usable by the storage device to transition from a lower power state to a higher power state.

The terms “lower power state” and “higher power state” refer to operational states of the storage device with different power levels. Although the examples described herein relate to transitioning from the PS0 state to the PS3, PS4, and RTD3 states and resuming from PS3, PS4, and RTD3 to the PS0 state, the subject matter described herein is not limited to these examples. HMB-assisted power state transitioning as described herein can be used to facilitate transition of a storage device between any power states in which storage device state information is needed for the resume operation. For example, Revision 1.2a of the NVMe Specification indicates that up to 32 power states can be used. The subject matter described herein may be used to facilitate transition between any of these or other storage device power states.

The term “bootstrap data” is used synonymously with “storage device state information.”

In some implementations, parity or data integrity check information may be stored prior to transitioning the storage device to a lower power state. “Parity information” as used herein is intended to refer to redundancy data or metadata that can be used for a signature integrity check of the bootstrap data stored in the HMB. Parity information may also refer to data usable to correct bit errors in the bootstrap data stored in the HMB. Parity information may also refer to a key that can serve for decryption of the bootstrap data stored in the HMB.

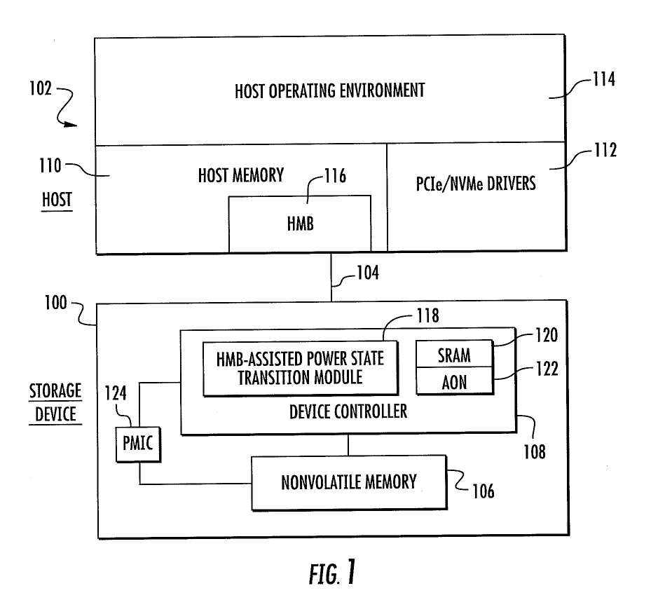

FIG. 1 is a block diagram illustrating a host system and a storage device where storage device uses the HMB maintained by the host device to assist in transitioning to and from different power states. In FIG. 1, storage device 100 is connected to a host device 102 via a bus 104. Storage device 100 includes non-volatile memory 106. Non-volatile memory 106 may be NAND flash memory, NOR flash memory, or a combination of NAND flash memory, NOR flash memory, and traditional spinning discs. Storage device 100 also includes a device controller 108 that controls accesses to non-volatile memory 106.

Host system 102 may be any suitable device that uses a non-volatile storage device, such as an SSD. For example, host device 102 may be an enterprise grade or retail grade device that interfaces with a flash-based storage system and operates as a self-contained or network accessible computing environment. Host device 102 may be any of a mobile device, a personal computer, a server, a cloud computer, a large/hyperscale storage appliance, or a combination of one or more of these.

Storage device 100 may be a flash-based storage system that is either removable or embedded within host device 102. For example, storage device 100 may be a solid state drive (SSD) or hybrid storage media (enterprise and client), that includes solid state components in combination with disc storage components. Storage device 100 may be locally or remotely connected to host 102.

Host device 102 includes a host memory 110, storage device drivers 112, and an operating environment 114. Host memory 110 may be implemented by DRAM and is used for operations of host device 102. In addition, host memory 110 may include HMB 116 that is usable by storage device 100 for performing some of its operations. Storage device drivers 112 may include PCIe and NVMe drivers for communicating with storage device 100 over bus 104. Host operating environment 114 may include an operating system, such as a Windows, IOS, or Android operating system.

In the illustrated example, device controller 108 includes an HMB-assisted power state transition module 118 that facilitates the transition of storage device 100 between power states by using storage device state information stored in HMB 116. For example, HMB-assisted power state transition module 118 may store at least a portion of storage device state information in HMB 116 in response to a host-initiated transition of storage device 100 to a lower power state and may facilitate in transitioning of storage device 100 from the lower power state using the state information stored in HMB 116.

Because HMB 116 can be reclaimed by host 102 when storage device 100 is in a low power state, and storage device 100 is not able to monitor HMB 116 when in the low power state, it may be desirable for storage device 100 to verify the contents of HMB 116 prior to attempting to resume. Alternatively, storage device 100 may resume using the current contents of HMB without first checking the validity of the storage state information. Either implementation is intended to be within the scope of the subject matter described herein.

Also illustrated in FIG. 1, storage device 100 includes SRAM 120 located on device controller 108 (i.e., onboard SRAM). SRAM 120 is typically small and is used to store device state information and FTL (flash translation layer structure) tables that are currently being used. In some power states, SRAM 120 may include an always on (AON) partition 122 that is used to store certain data, such as parity information, that can be used to verify the validity of bootstrap information stored in HMB 116. However, in other power states, power may not be maintained to SRAM 120 and AON partition 122 may therefore not be available to store parity or other information.

In FIG. 1, storage device 100 further includes a power management controller (PMIC) 124 that regulates power used by device controller 108 and non-volatile storage 106. PMIC 124 may also be used as an off-chip element (i.e., on a separate chip from device controller 106) for storing parity and bootstrap data address information before storage device 100 transitions to a lower power state. PMIC 124 may be volatile in that data loss may occur when power is cut to storage device 100. However, if PMIC 124 is maintained in a low power state, PMIC 124 may be used to store the parity and bootstrap data address information prior to transitioning to a lower power state. During a resume operation from the lower power state, the parity and bootstrap data address information may be read from PMIC 124 and used to access and verify the integrity of the bootstrap data stored in HMB 116.

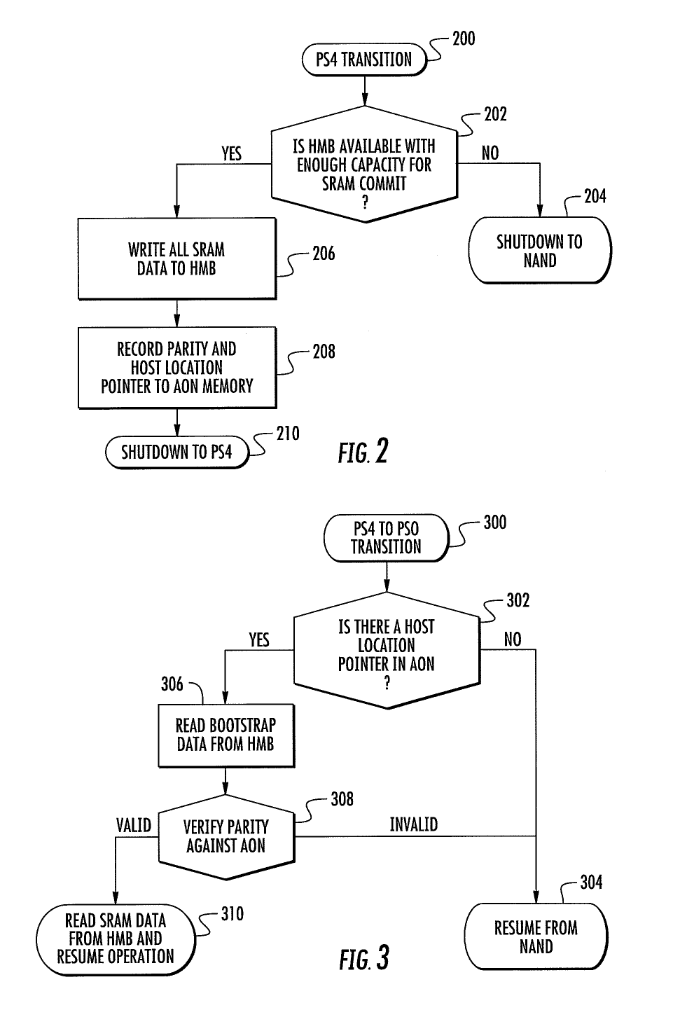

FIG. 2 is a flow chart illustrating an exemplary process for transitioning to a PS4 low power state from a current power state when AON partition 122 is available. Referring to FIG. 2, in step 200, storage device 100 initiates a transition to the PS4 state. The transition may be initiated in response to a set features command from host 102. In step 202, storage device 100 determines whether the HMB is available and has enough capacity to store the content of SRAM 120 needed for resuming operations from the PS4 state. Step 202 may be implemented by HMB-assisted power state transition module 118. HMB-assisted power state transition module 118 may determine whether HMB 116 is available by checking whether HMB has been allocated by host 102. HMB-assisted power state transition module 118 may determine whether the capacity of HMB 116 is sufficient to store the needed SRAM contents by comparing the amount of space allocated by the host to the amount of space used in SRAM 120 to store the data needed to resume. Exemplary data needed to be resumed may include active firmware code, FTL tables, processor state information, etc. Transient write buffers maintained in SRAM 120 may be excluded and not written to HMB 116.

In step 202, if there is insufficient space or if HMB 116 is not available, control proceeds to step 204 where the contents of SRAM are stored in non-volatile memory 106. If, however, the HMB is available and has sufficient capacity to store the contents of SRAM needed to initiate the transition from the lower power state, control proceeds to step 206 where the SRAM data is written to HMB 116. Again, this step may be performed by HMB-assisted power state transition module 118. HMB-assisted power state transition module 118 may perform this operation by writing the needed contents of SRAM 120 to HMB 116 across bus 104. In step 208, the parity information and the host location pointer that points to the stored state information are recorded in AON 122. Step 208 may be performed by HMB-assisted power state transition module 118 by calculating parity or other error detecting codes for bootstrap data stored in HMB 116. HMB-assisted power state transition module 118 may likewise store a pointer to the location in HMB 116 where the bootstrap data is stored.

In step 210, the storage device transitions to the PS4 state. Transitioning to the PS4 state may include shutting down power to device controller 108 or other components of storage device 100 that maintaining a minimal amount of power so that AON 122 can store the address and parity information.

To save time during resume, firmware code and NVMe state information may also be written from SRAM 120 to HMB 116 in step 206. In this case, the initial code used to reinitialize controller 108, and the PCIe interface must be present in the boot ROM of controller 108 or a similar location in order to avoid a need to read this code from NAND.

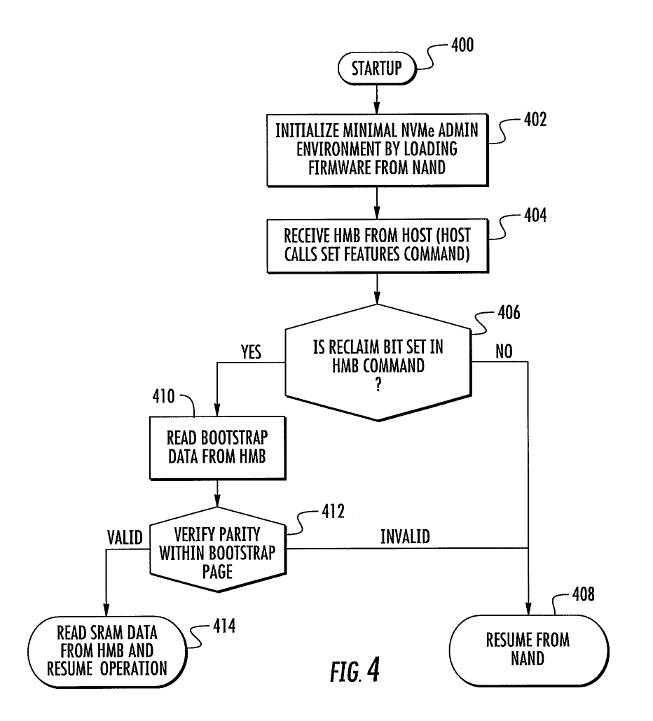

FIG. 3 is a flow chart illustrating an exemplary process that may be implemented by storage device 100 to resume from the PS4 state prior to receiving any information from the host about the state of HMB 116. Referring to FIG. 3, in step 300, storage device 100 initiates a transition from the PS4 to the PS0 state. Step 300 may be initiated in response to receiving an NVMe Set Features command from host 102 specifying the new power state. In step 302, storage device 100 determines whether there is a host location pointer in AON 122. Step 302 may be implemented by HMB-assisted power state transition module 118 reading the contents of AON 122 to determine whether a pointer to a location in HMB 116 is present. If the pointer is not present, control proceeds to step 304 where the resume operation is performed from non-volatile storage 106. This step may be performed by HMB-assisted power state transition module 118 reading the necessary data from non-volatile memory 106 and initializing SRAM 120 accordingly. As stated above, in an alternate implementation, HMB-assisted power state transition module may check PMIC 124 to determine whether PMIC 124 stores the pointer to the bootstrap data and/or parity information.

In step 302, if it is determined that AON partition 122 stores a location pointer, control proceeds to step 306 where bootstrap data is read from HMB 116. Step 306 may be performed by HMB-assisted power state transition module 118 reading the contents of HMB 116 at the location specified by the pointer. In step 308, the integrity of the data read from HMB 116 is verified. Verifying the integrity may be performed by HMB-assisted power state transition module 118 comparing the parity or other integrity checks calculated from the data retrieved from HMB 116 with the stored parity or data integrity check stored in the AON partition 122 of SRAM 120. If the data is invalid, control proceeds to step 304 where the resume is conducted from the data stored in non-volatile storage 106. If the integrity check indicates that the data is valid, control proceeds to step 310 where the SRAM data is read from HMB 116 and the resume operation is conducted using this data. Step 310 may be performed by HMB-assisted power state transition module 118 reading the contents of HMB 116 and initializing device controller 108 using the bootstrap data stored in HMB 116 prior to the transition to PS4 state.

It should be noted that context load from HMB to SRAM may be performed on demand, rather than prior to resuming full operation, in order to accelerate the transition to the PS0 state. In this case, a page table may be added on device 100 that indicates which portions of the SRAM are present and which are in the HMB.

According to another aspect of the subject matter described herein, HMB-assisted power state transition module may facilitate transition to a run time D3 (RTD3) state. This transition is similar to the transition to the PS4 state, but requires a full shutdown (power off) of device 100 as entry and a full startup sequence as exit. Within the RTD3 power state, HMB 116 may be used to store the contents of SRAM 120 needed for startup or resume. However, AON 122 is not available to store parity and pointer information because device 100 is fully powered down. Accordingly, storage device 100 may store parity and data pointer location information in non-volatile memory, such as EEPROM or NAND and follow the sequence illustrated in FIG. 3 with the exception that in step 302, the host pointer may be retrieved from NAND or EEPROM, rather than AON 122.

According to yet another aspect of the subject matter described herein, storage device 100 may store the pointer and parity information in HMB 116. In such an example, storage device 100 may perform the steps illustrated in FIG. 2 to store the SRAM data needed for transitioning from a lower power state in HMB 116. In addition, storage device 100 may also store the parity and pointer information in HMB 116.

When performing a resume operation, storage device 100 may do a partial initialization of the NVMe environment by loading a small firmware bootstrap from NAND and then resuming full operation after the host reinitializes HMB 116. The host can then indicate to the device during the reinitialization that the HMB contains the same data as previously stored prior to the RTD3 transition.

FIG. 4 is a flow chart illustrating the resume from a low power state, such as RTD3, when HMB 116 is used to store the parity and pointer information for the bootstrap data. Referring to FIG. 4, in step 400, host device 102 initiates a startup or transition of storage device 100 to a higher power state. In step 402, device 100 initializes minimal NVMe administrative environment by loading firmware from non-volatile memory 106 and/or ROM. Step 402 may be implemented by HMB-assisted power state transition module 118 reading the appropriate firmware from non-volatile memory 106 and/or ROM and loading the firmware in SRAM 120.

In step 404, the HMB is allocated by the host and the existence of the HMB is communicated to device controller 100. Step 404 may be implemented by an NVMe Set Features command sent by host 102 to device 100 over bus 104. In step 406, it determined whether the Memory Return (reclaim) bit is present within the Set Features command. Step 406 may be performed by HMB-assisted power state transition module 118 reading the contents of the set features command to determine whether the host has allocated the same HMB that was present prior to the transition to the lower power state. If the reclaim bit is not set, then the HMB is not the same as prior to shutdown. Accordingly, control proceeds to step 408 where the resume is conducted using the data stored in non-volatile memory 106.

If, on the other hand, the reclaim bit is set in the set features command, control proceeds to step 410 where the bootstrap data is read from the HMB. Step 410 may be performed by HMB-assisted power state transition module 118 reading the bootstrap data from HMB 116 and reading the parity information from HMB 116.

In step 412, the integrity of the bootstrap data is verified. Step 412 may be implemented by HMB-assisted power state transition module 118 calculating a parity or other integrity check code on the bootstrap data retrieve from HMB 116 and comparing the data integrity calculation results to the data integrity information obtained from HMB 116. If the parity check indicates that the data is invalid, control proceeds to step 408 where the resume is conducted using bootstrap information stored in non-volatile memory 106. If the data integrity check indicates that the bootstrap data is valid, control proceeds to step 414 where the resume is conducted using the data stored in HMB 116.

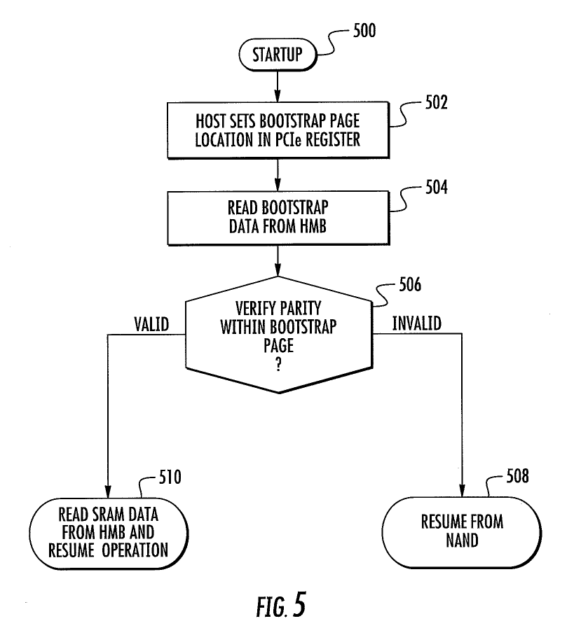

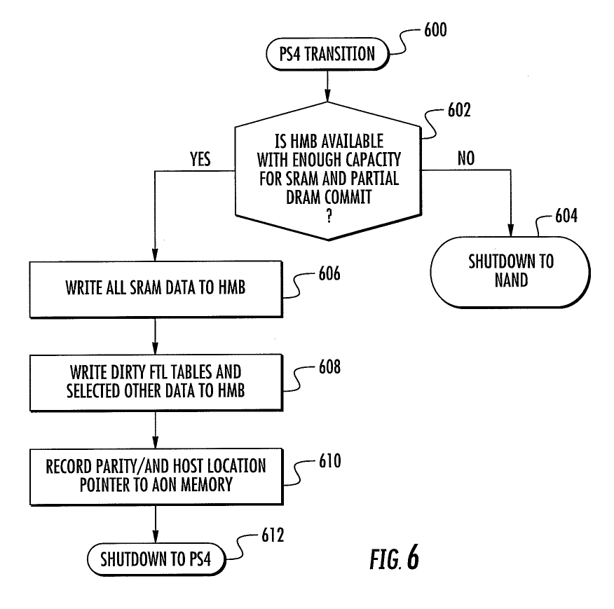

As an alternative to having the storage device retrieve the data integrity check and bootstrap location from the HMB via a read out operation, in another alternative, the host may inform the storage device of the location of the HMB and also the parity information by writing to a device register, such as a PCIe register. FIG. 5 illustrates such an example. In FIG. 5, the flow chart illustrates steps performed by the host and the storage device when transitioning from a low power state to a higher power state. The steps in FIG. 5 assume that the storage device has already stored the bootstrap data and parity information in the HMB. Referring to FIG. 5, in step 500, the storage device initiates a startup or resume routine in response to a command from the host. In step 502, the host informs the storage device of the bootstrap location by writing the location in a PCIe register. In step 504, the device uses the location to retrieve the bootstrap data from the HMB. Step 504 may be performed by HMB-assisted power state transition module 118. In step 506, it is determined whether the retrieved bootstrap data is valid. Step 506 may be implemented by HMB-assisted power state transition module 118 calculating parity or other integrity check from the retrieved bootstrap data and comparing the calculated data integrity check information to the information retrieved from the HMB.

In step 506, if the data integrity check fails, control proceeds to step 508 where storage device 100 resumes operations using bootstrap information stored in non-volatile memory 106. If the data integrity check passes in step 506, control proceeds to step 510 where the storage device uses the bootstrap data retrieved from the HMB to resume operations. Step 510 may be performed by HMB-assisted power state transition module 118 using the data read from HMB 116.

HMB-assisted transitioning between storage device power states may also be useful with storage devices that include onboard DRAM, especially in situations where the DRAM is powered off when in the low power state and therefore unusable to store bootstrap data. In such a situation, more host DRAM may be required to capture all of the storage device DRAM contents prior to power off. Storage device 100 may intelligently decide which DRAM data should be stored in the HMB to allow fast resume and which should be committed to NAND. Such operations may be performed by HMB-assisted power state transition module 118. In one example, modified FTL tables may be committed to HMB rather than flushing them to NAND during a transition to the PS4 state. Similarly, uncommitted write coalescing buffers may be committed to HMB, rather than NAND during this transition.

FIG. 6 is a flow chart illustrating exemplary steps that may be performed by HMB-assisted power state transition module 118 when transitioning to the PS4 state in a device that includes onboard DRAM. Referring to FIG. 6, in step 600, a PS4 transition is initiated. Step 600 may be initiated by the storage device in response to receiving a command from the host to transition to the PS4 state. In step 602, it is determined whether the HMB is available with sufficient capacity to store SRAM and partial DRAM information needed for resuming. This step may be performed by selecting the contents of SRAM and DRAM required for initiating the transfer from the PS4 state and determining whether there is sufficient HMB space for committing the information to the HMB. If the HMB is not available or there is insufficient space in the HMB, control proceeds to step 604 where the data is committed to NAND.

If in step 602 it is determined that there is sufficient HMB capacity, control proceeds to step 606 where all SRAM data is copied to the HMB. In step 608, dirty FTL tables and selected information from the storage device DRAM are written to the HMB. Dirty FTL tables refer to those which include LBA ranges that are modified due to previous write or maintenance operations but were not yet written to the storage device. Other examples of data that may be written from DRAM to the HMB include state information for various processes running in the device controller, firmware overlays, or partially staged metadata.

In step 610, parity and the host location pointer that points to the bootstrap data is recorded in AON partition 122. In step 612, the storage device shuts down to the PS4 state.

When resuming from the PS4 to the PS0 state, similar resume steps may be performed as the SRAM resume flows described above. For example, the storage device may determine the location of the HMB using the AON partition, a PCIe register, or a minimal NVMe environment that receives the HMB pointer. Thus, even in devices where the storage device includes onboard DRAM, HMB-assisted transitions between power states may reduce transition time.

The subject matter described herein can be implemented in any suitable NAND flash memory, including 2D or 3D NAND flash memory. Semiconductor memory devices include volatile memory devices, such as dynamic random access memory (“DRAM”) or static random access memory (“SRAM”) devices, nonvolatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that the subject matter described herein is not limited to the two dimensional and three dimensional exemplary structures described but cover all relevant memory structures within the spirit and scope of the subject matter as described herein and as understood by one of skill in the art.

The subject matter described herein may be implemented in hardware, software, firmware, or any combination thereof. As such, the terms “function” “node” or “module” as used herein refer to hardware, which may also include software and/or firmware components, for implementing the feature being described. In one exemplary implementation, the subject matter described herein may be implemented using a computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

It will be understood that various details of the subject matter described herein may be changed without departing from the scope of the subject matter described herein. Furthermore, the foregoing description is for the purpose of illustration only, and not for the purpose of limitation.

What is claimed is:

1. A storage device comprising:
non-volatile memory;
a device controller for controlling access to the non-volatile memory; and
a host memory buffer (HMB)-assisted power state transition module operatively associated with the device controller for storing storage device state information in a host memory buffer (HMB) in memory of host device separate from the storage device prior to the storage device entering a lower power state and for using the state information stored in the HMB to transition the storage device from the lower power state to a higher power state.

2. The storage device of claim 1 wherein the HMB-assisted power state transition module is configured to store data integrity check information for the state information stored in the HMB and address information for the state information stored in the HMB in an always on (AON) partition of static random access memory (SRAM) associated with the device controller.

3. The storage device of claim 2 wherein the HMB-assisted power state transition module is configured to use the address information to access the state information stored in the HMB and the data integrity check information to check the integrity of the state information stored in the HMB.

4. The storage device of claim 3 wherein the HMB-assisted power state transition module is configured to transition to the higher power state using state information retrieved from the non-volatile memory in response to a failure of the data integrity check.

5. The storage device of claim 3 wherein the HMB-assisted power state transition module is configured to transition the storage device to the higher power state using the state information retrieved from the HMB in response to passing of the data integrity check.

6. The storage device of claim 1 wherein the HMB-assisted power state transition module is configured to store data integrity check and address information for the state information stored in the HMB in the HMB and to retrieve the state information from the HMB and verify its integrity using the address and data integrity information stored in the HMB.

7. The storage device of claim 1 wherein the HMB-assisted power state transition module is configured to receive, via a register write from the host, an address in the HMB where the state information is stored and to use the address to retrieve the state information from the HMB.

8. The storage device of claim 7 wherein the register write includes a peripheral control interface express (PCIe) register write.

9. The storage device of claim 1 comprising dynamic random access memory (DRAM) located on the storage device, wherein the HMB-assisted power state transition module stores at least a portion of the storage device state information stored in the DRAM in the HMB prior to the storage device transitioning to the lower power state.

10. The storage device of claim 1 comprising a power management controller, wherein the HMB-assisted power state transition module is configured to store data integrity check information for the state information stored in the HMB and address information for the state information stored in the HMB in the power management controller.

11. The storage device of claim 1 wherein the HMB-assisted power state transition module is configured to store data error correcting and/or decryption key information prior to the storage device transitioning to the lower power state.

12. The storage device of claim 1 wherein the lower power state comprises one of a PS3 state, a PS4 state, and a runtime D3 (RTD3) state and wherein the higher power state comprises a PS0 state.

13. A method comprising:
in a storage device including nonvolatile memory and device controller for controlling access to the non-volatile memory:
storing storage device state information in a host memory buffer (HMB) in memory of a host device separate from the storage device prior to the storage device entering a lower power state; and
using the state information stored in the HMB to transition the storage device from the lower power state to a higher power state.

14. The method of claim 13 comprising storing data integrity check information for the state information stored in the HMB and address information for the state information stored in the HMB in an always on (AON) partition of static random access memory (SRAM) associated with the device controller.

15. The method of claim 14 comprising using the address information to access the state information stored in the HMB and the data integrity check information to check the integrity of the state information stored in the HMB.

16. The method of claim 15 comprising transitioning to the higher power state using state information retrieved from the non-volatile memory in response to a failure of the data integrity check.

17. The method of claim 15 comprising transitioning the storage device to the higher power state using the state information retrieved from the HMB in response to passing of the data integrity check.

18. The method of claim 13 comprising storing data integrity check and address information for the state information stored in the HMB in the HMB and retrieving the state information from the HMB using the address information and data integrity information stored in the HMB.

19. The method of claim 13 comprising receiving via a register write from the host, an address in the HMB where the state information is stored and using the address to retrieve the state information from the HMB.

20. The method of claim 19 wherein the register write includes a peripheral control interface express (PCIe) register write.

21. The method of claim 13 comprising providing dynamic random access memory (DRAM) located on the storage device, and wherein storing the storage device state information in the HMB comprises storing at least a portion of the storage device state information stored in the DRAM in the HMB prior to the storage device transitioning to the lower power state.

22. The method of claim 13 wherein the lower power state comprises one of a PS3 state, a PS4 state, and a runtime D3 (RTD3) state and wherein the higher power state comprises a PS0 state.

23. The method of claim 13 comprising storing data integrity check information for the state information stored in the HMB and address information for the state information stored in the HMB in a power management controller.

24. The method of claim 13 comprising storing data error correcting and/or decryption key information prior to the storage device transitioning to the lower power state.

25. A non-transitory computer readable medium having stored thereon executable instructions that when executed by the processor of a computer control the computer to perform steps comprising:
in a storage device including nonvolatile memory and device controller for controlling access to the non-volatile memory:
storing storage device state information in a host memory buffer (HMB) in memory of a host device separate from the storage device prior to the storage device entering a lower power state; and
using the state information stored in the HMB to transition the storage device from the lower power state to a higher power state.
